(19) United States
(12) Patent Application Publication
(10) Pub. No.: US 2015/0229333 A1
(43) Pub. Date: Aug. 13, 2015

(54) Systems and Methods for Rank Deficient Encoding

(71) Applicant: LSI Corporation, San Jose, CA (US)

(72) Inventors: Dmitriy V. Alekseev, Moscow (RU); Pavel A. Panteleev, Moscow (RU); Elyar E. Gasanov, Moscow (RU); Andre P. Sokolov, Moscow (RU); Yuri Shutkin, Moscow (RU)

(21) Appl. No.: 14/470,911

(22) Filed: Aug. 27, 2014

(30) Foreign Application Priority Data
Feb. 10, 2014 (RU) 2014104573/08

(51) Int. Cl. H03M 13/15; H03M 13/00

(52) U.S. Cl. CPC H03M 13/15; H03M 13/616

(57) ABSTRACT

The present inventions are related to systems and methods for data processing, and more particularly to systems and methods for data encoding.

### CROSS REFERENCE TO RELATED APPLICATIONS

The present application claims priority to Russian Patent App. No. 2014104573 entitled “Systems and Methods for Rank Deficient Encoding”, and filed Feb. 10, 2014 by Alekseev et al. The entirety of the aforementioned patent application is incorporated herein by reference for all purposes.

### FIELD OF THE INVENTION

The present inventions are related to systems and methods for data processing, and more particularly to systems and methods for data encoding.

### BACKGROUND

Various data transfer systems have been developed including storage systems, cellular telephone systems, and radio transmission systems. In each of the systems data is transferred from a sender to a receiver via some medium. For example, in a storage system, data is sent from a sender (i.e., a write function) to a receiver (i.e., a read function) via a storage medium. Encoding may involve vector multiplication by a quasi-cyclic matrices. However, not all scenarios allow for use of quasi-cyclic matrices, but rather involve rank deficient matrices. Encoding using rank deficient matrices is relatively complex, and thus costly in terms of both circuit area and power consumption.

Hence, for at least the aforementioned reasons, there exists a need in the art for advanced systems and methods for data processing.

### SUMMARY

The present inventions are related to systems and methods for data processing, and more particularly to systems and methods for data encoding.

Various embodiments of the present invention provide data processing systems that include an encoder circuit. The encoder circuit is operable to: receive a user data input; matrix multiply the user data input by a first quasi-cyclic parity component to yield a first interim value; matrix multiply the first interim value by an inverse left factor Smith Normal component to yield a second interim value; matrix multiply the second interim value by a pseudo inverse diagonal factor Smith Normal component to yield a third interim value; matrix multiply the third interim value by an inverse right factor Smith Normal component to yield a first parity portion; matrix multiply the first parity portion by a second quasi-cyclic parity component to yield a fourth interim value; and vector add the first interim value to the fourth interim value to yield a second parity portion.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 shows a storage system including rank deficient LDPC encoder circuitry in accordance with various embodiments of the present invention;

FIG. 2 shows a data transmission device including a transmitter having rank deficient LDPC encoder circuitry in accordance with various embodiments of the present invention;

FIG. 3 shows a solid state memory circuit including a data processing circuit having rank deficient LDPC encoder circuitry in accordance with some embodiments of the present invention;

FIG. 4a shows a processing system including a rank deficient LDPC encoder circuit in accordance with some embodiments of the present invention;

FIG. 4b shows one implementation of the rank deficient LDPC encoder circuit in accordance with one or more embodiments of the present invention;

FIG. 5 is a flow diagram showing a method in accordance with one or more embodiments of the present invention for rank deficient LDPC encoding; and

FIG. 6 is a flow diagram showing a method in accordance with various embodiments of the present invention for generating encoding components.

### DETAILED DESCRIPTION OF SOME EMBODIMENTS

The present inventions are related to systems and methods for data processing, and more particularly to systems and methods for data encoding.

Various embodiments of the present invention provide data processing systems that include an encoder circuit. The encoder circuit is operable to: receive a user data input; matrix multiply the user data input by a first quasi-cyclic parity component to yield a first interim value; matrix multiply the first interim value by an inverse left factor Smith Normal component to yield a second interim value; matrix multiply the second interim value by a pseudo inverse diagonal factor Smith Normal component to yield a third interim value; matrix multiply the third interim value by an inverse right factor Smith Normal component to yield a first parity portion; matrix multiply the first parity portion by a second quasi-cyclic parity component to yield a fourth interim value; and vector add the first interim value to the fourth interim value to yield a second parity portion. In some cases, the data processing systems are implemented as part of a storage device. In other cases, the data processing systems are implemented as part of a communication device. In some instances of the aforementioned embodiments, the data processing systems are implemented as part of an integrated circuit.

In various instances of the aforementioned embodiments, the encoder circuit is further operable to assemble at least the user data input, the first parity portion, and the second parity portion into an encoded codeword. In some instances of the aforementioned embodiments, the encoder circuit is further operable to matrix multiply the user data input by a third quasi-cyclic parity component to yield a third parity portion. In some such instances, the encoder circuit is further operable to assemble the user data input, the first parity portion, the second parity portion and the third parity portion into an encoded codeword. In various cases, the encoder circuit includes a memory operable to store the first quasi-cyclic parity component, the inverse left factor Smith Normal component, the pseudo inverse diagonal factor Smith Normal component, the inverse left factor Smith Normal component, and the second quasi-cyclic parity component. In some such cases, the encoder circuit includes: a first matrix multiplier circuit operable to matrix multiply the user data input by the first quasi-cyclic parity component to yield the first interim value; a second matrix multiplier circuit operable to matrix multiply the first interim value by the inverse left factor Smith Normal component to yield the second interim value; a third matrix multiplier circuit operable to matrix multiply the second interim value by the pseudo inverse diagonal factor Smith Normal component to yield the third interim value; a fourth matrix multiplier circuit operable to matrix multiply the third interim value by the inverse right factor Smith Normal component to yield the first parity portion; a fifth matrix multiplier circuit operable to matrix multiply the first parity portion by a second quasi-cyclic parity component to yield a fourth interim value; a vector addition circuit operable to vector add the first interim value to the fourth interim value to yield the second parity portion; and a sixth matrix multiplier circuit operable to matrix multiply the user data input by the third quasi-cyclic parity component to yield the third parity portion. In particular cases, each of the first matrix multiplier circuit, the second matrix multiplier circuit, the fourth matrix multiplier circuit, the fifth matrix multiplier circuit, and the sixth matrix multiplier circuit are configured to multiply an input by a quasi-cyclic matrix. In addition, the third matrix multiplier circuit is configured to multiply an input by a non-quasi-cyclic matrix. In one or more instances, the pseudo inverse diagonal factor Smith Normal component is a non-quasi-cyclic component, and both the inverse right factor Smith Normal component and the inverse left factor Smith Normal component are quasi-cyclic components.

Other embodiments of the present invention provide methods for data encoding. The methods include: calculating components for a rank deficient encoder, where the component calculation includes applying a Smith Normal conversion to an input matrix that yields left factor Smith Normal component, a diagonal factor Smith Normal conversion, and a right factor Smith Normal component; inverting the left factor Smith Normal component to yield an inverse left factor Smith Normal component, where the inverse left factor Smith Normal component is a quasi-cyclic matrix; inverting the diagonal factor Smith Normal component to yield a pseudo inverse diagonal factor Smith Normal component, where the pseudo inverse diagonal factor Smith Normal component is a non-quasi-cyclic matrix; inverting the right factor Smith Normal component to yield an inverse left factor Smith Normal component, where the inverse left factor Smith Normal component is a quasi-cyclic matrix; and storing the inverse left factor Smith Normal component, the pseudo inverse diagonal factor Smith Normal component, and the inverse right factor Smith Normal component to a memory device.

In some instances of the aforementioned embodiments, the methods further include: receiving a user data input; matrix multiplying the user data input by a first quasi-cyclic parity component to yield a first interim value; matrix multiplying the first interim value by the inverse left factor Smith Normal component to yield a second interim value; matrix multiplying the second interim value by the pseudo inverse diagonal factor Smith Normal component to yield a third interim value; matrix multiplying the third interim value by the inverse right factor Smith Normal component to yield a first parity portion; matrix multiplying the first parity portion by a second quasi-cyclic parity component to yield a fourth interim value; and vector adding the first interim value to the fourth interim value to yield a second parity portion. In some cases, the method further includes matrix multiplying the user data input by a third quasi-cyclic parity component to yield a third parity portion. In some cases, the methods further include assembling the user data input, the first parity portion, the second parity portion and the third parity portion into an encoded codeword.

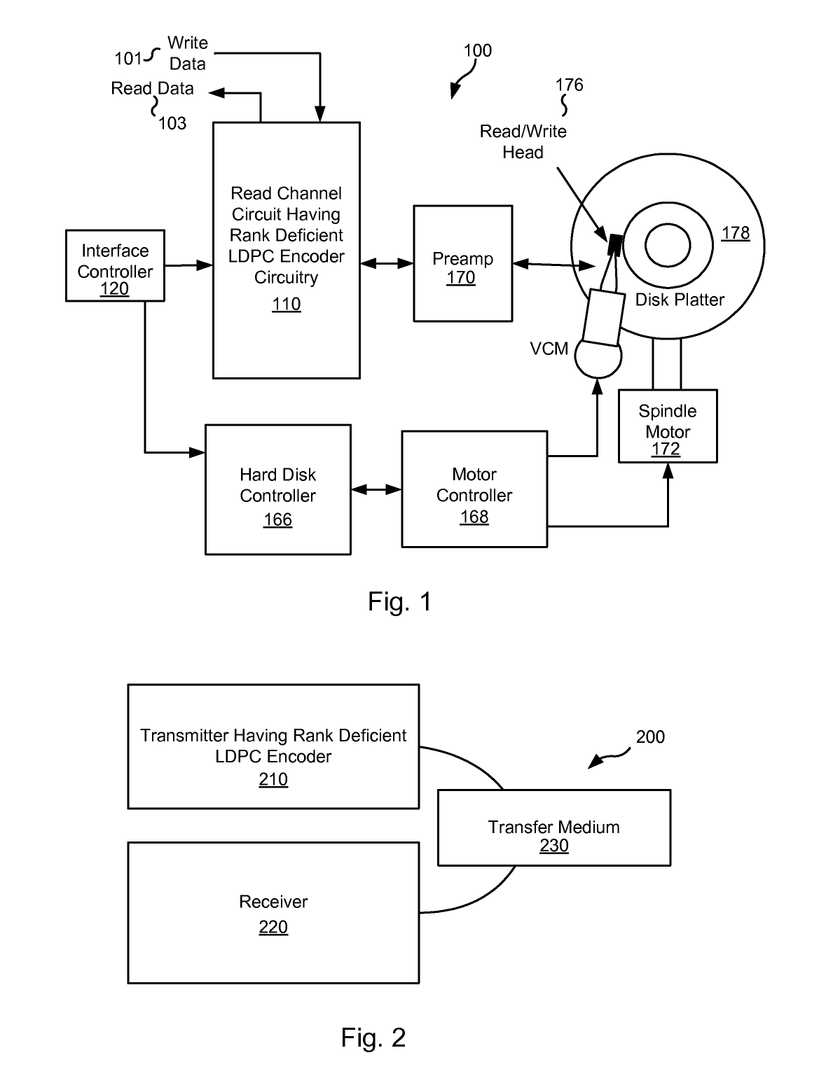

Turning to FIG. 1, a storage system 100 is shown that includes a read channel 110 rank deficient LDPC encoder circuitry in accordance with one or more embodiments of the present invention. Storage system 100 may be, for example, a hard disk drive. Storage system 100 also includes a preamplifier 170, an interface controller 120, a hard disk controller 166, a motor controller 168, a spindle motor 172, a disk platter 178, and a read/write head 176. Interface controller 120 controls addressing and timing of data to/from disk platter 178, and interacts with a host controller (not shown). The data on disk platter 178 consists of groups of magnetic signals that may be detected by read/write head assembly 176 when the assembly is properly positioned over disk platter 178. In one embodiment, disk platter 178 includes magnetic signals recorded in accordance with either a longitudinal or a perpendicular recording scheme.

In a typical read operation, read/write head 176 is accurately positioned by motor controller 168 over a desired data track on disk platter 178. Motor controller 168 both positions read/write head 176 in relation to disk platter 178 and drives spindle motor 172 by moving read/write head assembly 176 to the proper data track on disk platter 178 under the direction of hard disk controller 166. Spindle motor 172 spins disk platter 178 at a determined spin rate (RPMs). Once read/write head 176 is positioned adjacent the proper data track, magnetic signals representing data on disk platter 178 are sensed by read/write head 176 as disk platter 178 is rotated by spindle motor 172. The sensed magnetic signals are provided as a continuous, minute analog signal representative of the magnetic data on disk platter 178. This minute analog signal is transferred from read/write head 176 to read channel circuit 110 via preamplifier 170. Preamplifier 170 is operable to amplify the minute analog signals accessed from disk platter 178. In turn, read channel circuit 110 decodes and digitizes the received analog signal to recreate the information originally written to disk platter 178. This data is provided as read data 103 to a receiving circuit. A write operation is substantially the opposite of the preceding read operation with write data 101 being provided to read channel circuit 110. This data is then encoded and written to disk platter 178.

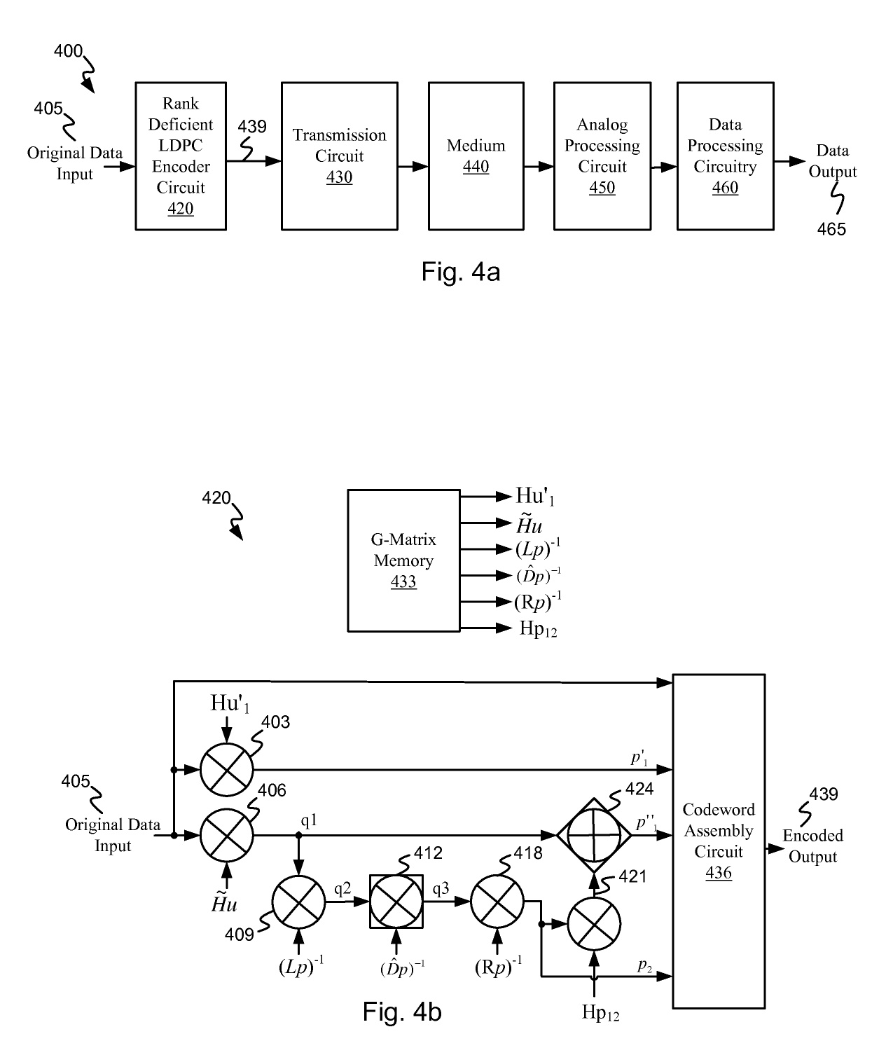

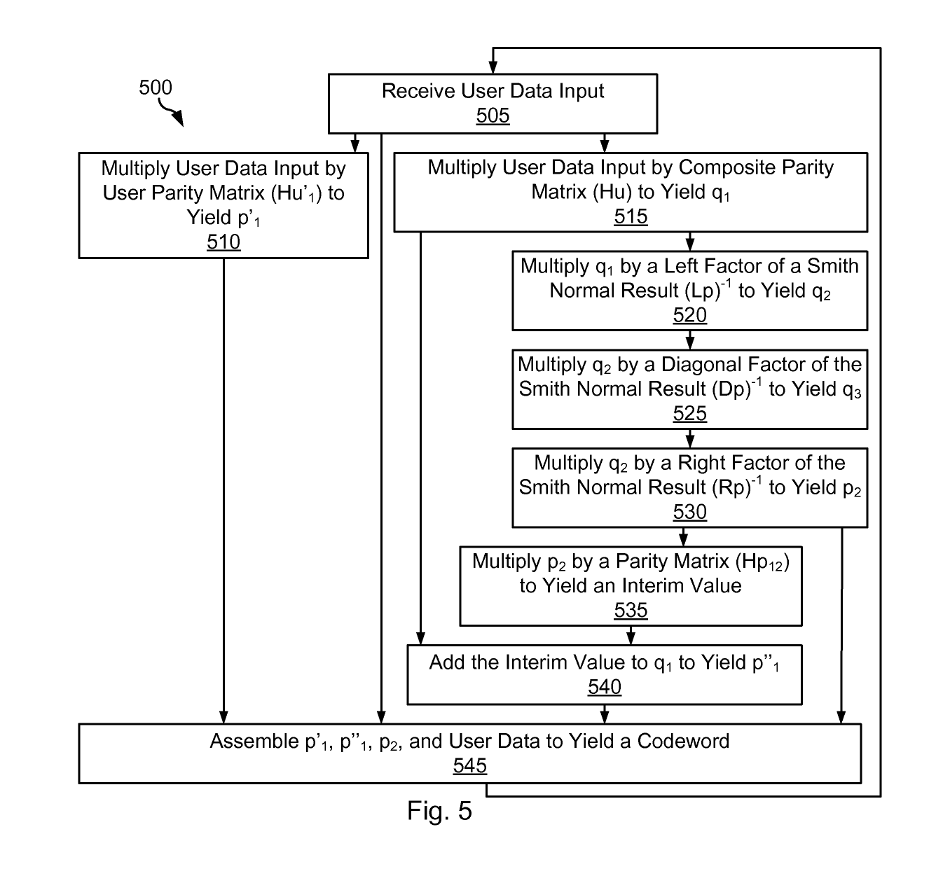

In operation, data stored to disk platter 178 is encoded using a rank deficient encoder circuit to yield an encoded data set. The encoded data set is then written to disk platter 178, and later accessed from disk platter and decoded using a decoder circuit. The rank deficient encoder circuit may be implemented similar to that discussed below in relation to FIG. 4b, and/or may operate similar to that discussed below in relation to FIG. 5.

It should be noted that storage system 100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

A data decoder circuit used in relation to read channel circuit 110 may be, but is not limited to, a low density parity check (LDPC) decoder circuit as are known in the art. Such low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

In addition, it should be noted that storage system 100 may be modified to include solid state memory that is used to store data in addition to the storage offered by disk platter 178. This solid state memory may be used in parallel to disk platter 178 to provide additional storage. In such a case, the solid state memory receives and provides information directly to read channel circuit 110. Alternatively, the solid state memory may be used as a cache where it offers faster access time than that offered by disk platted 178. In such a case, the solid state memory may be disposed between interface controller 120 and read channel circuit 110 where it operates as a pass through to disk platter 178 when requested data is not available in the solid state memory or when the solid state memory does not have sufficient storage to hold a newly written data set. Based upon the disclosure provided herein, one of ordinary skill in the art will recognize a variety of storage systems including both disk platter 178 and a solid state memory.

Turning to FIG. 2, a data transmission system 200 including a transmitter 210 having rank deficient LDPC encoder circuitry in accordance with one or more embodiments of the present invention. Transmitter 210 transmits encoded data via a transfer medium 230. Transfer medium 230 may be a wired or wireless transfer medium. Based upon the disclosure provided herein, one of ordinary skill in the art will recognize a variety of transfer mediums that may be used in relation to different embodiments of the present invention. The encoded data is received from transfer medium 230 by receiver 220. In operation, transmitter encodes user data using a rank deficient encoder circuit to yield an encoded data set. The encoded data set is then transmitted via transfer medium 230 to receiver 220. The rank deficient encoder circuit may be implemented similar to that discussed below in relation to FIG. 4b, and/or may operate similar to that discussed below in relation to FIG. 5.

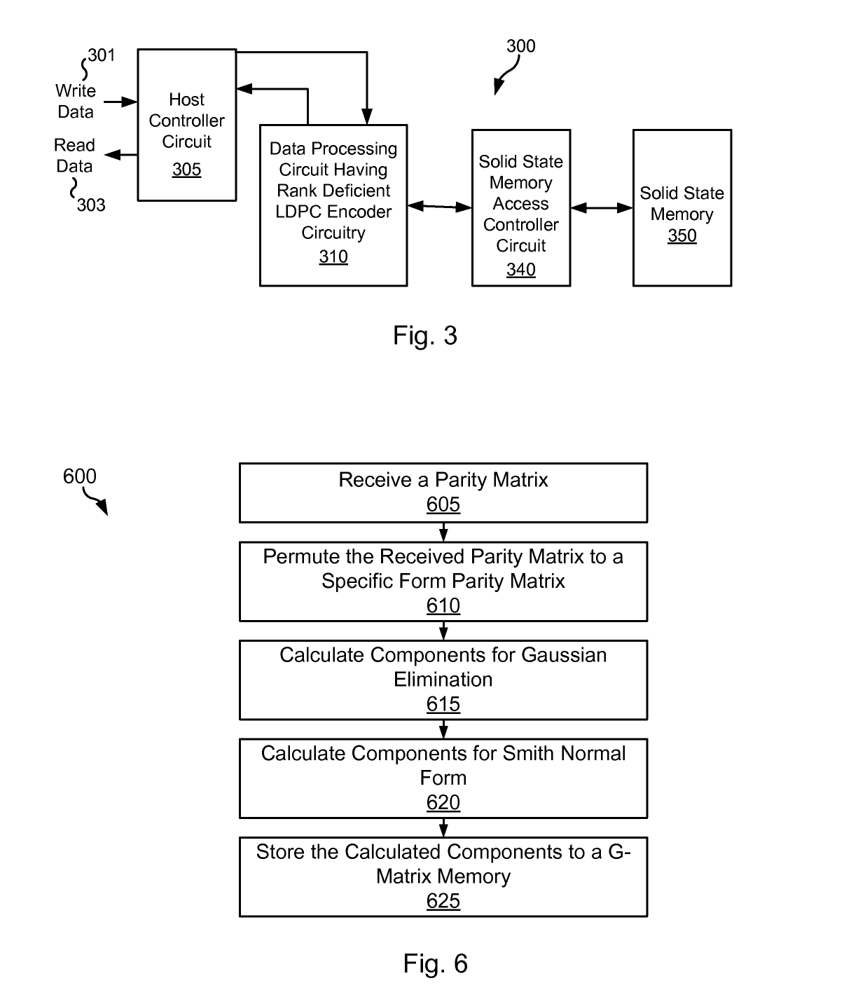

Turning to FIG. 3, another storage system 300 is shown that includes a data processing circuit 310 having rank deficient LDPC encoder circuitry in accordance with one or more embodiments of the present invention. A host controller circuit 305 receives data to be stored (i.e., write data 301). Solid state memory access controller circuit 340 may be any circuit known in the art that is capable of controlling access to and from a solid state memory 350. Solid state memory access controller circuit 340 encodes a received data set to yield an encoded data set. The encoding is done using a rank deficient LDPC encoder circuit, and results in an encoded data set that is stored to solid state memory 350. Solid state memory 350 may be any solid state memory known in the art. In some embodiments of the present invention, solid state memory 350 is a flash memory. The rank deficient encoder circuit may be implemented similar to that discussed below in relation to FIG. 4b, and/or may operate similar to that discussed below in relation to FIG. 5. Later, when the previously written data is to be accessed from solid state memory 350, solid state memory access controller circuit 340 requests the data from solid state memory 350 and provides the requested data to data processing circuit 310. In turn, data processing circuit 310 decodes the encoded data to yield the originally received user data.

Turning to FIG. 4a, a data processing system 400 is shown that includes a rank deficient LDPC encoder circuit 420 in accordance with some embodiments of the present invention. Data processing system 400 includes rank deficient LDPC encoder circuit 420 that applies a rank deficient encoding algorithm to an original data input 405 to yield an encoded output 439. Application of the rank deficient encoding algorithm includes performing a number of vector multiplications by quasi-cyclic matrices and another multiplication by a non-quasi-cyclic matrix of a smaller size that the quasi-cyclic matrices.

In a traditional encoding, sparse matrices are used that are represented in quasi-cyclic form. In particular, a matrix is represented in block form such as:

$$( \begin{matrix}{H}_{1 , 1} & … & {H}_{1 , n} \\ … & … & … \\ {H}_{m , 1} & … & {H}_{m , n}\end{matrix} ) ,$$

where each block (H_{i,j}) of size C×C is either a zero matrix or a cyclic matrix such as:

$${H}_{i , j} = ( \begin{matrix}{a}_{1} & {a}_{2} & … & {a}_{c} \\ {a}_{c} & {a}_{1} & … & {a}_{c - 1} \\ {a}_{2} & {a}_{3} & … & {a}_{1}\end{matrix} ) .$$

It should be noted that a quasi-cyclic matrix that includes only one non-zero element in each row of H_{i,j} is referred to as an identity matrix with rows shifted cyclically by the same value. Using such an identity matrix requires only the storage of the shift values for each circulant. Using linear algebra, a matrix (M) may be represented in a Smith Normal Form as a products of matrices in accordance with the following equation:

M=L×D×R,

where L is a left matrix, R is a right matrix, and D is a diagonal matrix. Conversion to the Smith Normal Form may be done similar to that discussed in K. R. Matthews, “Smith Normal Form. MP274: Linear Algebra, Lecture Notes”, University of Queensland 1991. The entirety of the aforementioned disclosure is incorporated herein by reference for all purposes.

Obtaining the components for the rank deficient encoding algorithm include the following processes: (1) permuting the columns and/or rows of a parity check matrix into an alternate form, (2) calculating a first portion of the parity bits using Gaussian elimination using a first part of the parity check matrix, and (3) using a Smith Normal form of a second part of the parity check matrix for calculation of a second portion of the parity bits.

Permuting the columns and/or rows of a parity check matrix into an alternate form includes taking a standard parity check matrix consisting of M×N circulant blocks of size C×C. Said another way, the matrix has M·C rows and N·C columns. Rows and columns of circulants are permuted so that the parity check matrix is in the form

$$H = ( \begin{matrix}{I}^{′} & 0 & 0 & {Hu}_{1}^{′} \\ 0 & {I}^{″} & {Hp}_{12} & {Hu}_{1}^{″} \\ {Hp}_{21}^{′} & {Hp}_{21}^{″} & {Hp}_{22}^{′} & {Hu}_{2}^{′}\end{matrix} ) ,$$

where 0 stands for all zero matrix, I′ and I″ stand for identity matrices of size M₁′·C and M₁″·C, respectively. Row blocks have the sizes: M₁′×C, M₁″×C and M₂×C respectively, where M₁′+M₁″+M₂=M Column blocks have sizes M₁′×C, M₁″×C, M₂×C, and K×C, where M₁′+M₁″+M₂+K=N.

All of the aforementioned Hu and Hp blocks are made of circulants. By denoting user bits (u) and parity bits (p) in the form (p,u), and splitting the parity bits into three component parts: p=(p₁′, p₁″, p₂), which have sizes M₁′×C, M₁″×C and M₂×C, respectively. Using such a notation, the parity check equations may be recast in the following format:

$$\{ \begin{matrix}{p}_{1}^{′} & & + {Hu}_{1}^{′} \times u = 0 \\ {p}_{1}^{″} & + {Hp}_{12} \times {p}_{2} & + {Hu}_{1}^{″} \times u = 0 \\ {Hp}_{21}^{′} \times {p}_{1}^{′} + {Hp}_{21}^{″} \times {p}_{1}^{″} & + {H}_{22}^{′} \times {p}_{2} & + {Hu}_{2} \times u = 0.\end{matrix}$$

The Hu₁′×u, Hu₁″×u and Hu₂×u components correspond to the user bits part of the parity check equations, and all of the other components correspond to the parity bits part of the parity check equations.

The Gaussian elimination is performed over the last block row of the aforementioned parity check equations to yield updated parity check equations:

$$\{ \begin{matrix}{p}_{1}^{′} & & & + {Hu}_{1}^{′} \times u = 0 \\ & {p}_{1}^{″} & + {Hp}_{12} \times {p}_{2} & + {Hu}_{1}^{″} \times u = 0 \\ & & + \tilde{H} p \times {p}_{2} & + \tilde{H} u \times u = 0 ,\end{matrix}$$

where \tilde{H}p=Hp₂₁′×Hp₁₂+Hp₂₂′, and \tilde{H}u=Hp₂₁′×Hu₁′+Hp₂₁′×Hu₁″+Hu₂. Of note, the p₁′ part of parity bits may be calculated instantly after all user bits (u) are received. Since the H matrix was rank deficient, the parity multiplier portion \tilde{H}p is also rank deficient and can not be inverted. Thus, p₂ cannot be calculated through simple multiplication by the inverse of the parity multiplier portion \tilde{H}p (i.e., (\tilde{H}p)⁻¹).

A circulant matrix

$$( e . g . , {H}_{i , j} = ( \begin{matrix}{a}_{1} & {a}_{2} & … & {a}_{c} \\ {a}_{c} & {a}_{1} & … & {a}_{c - 1} \\ {a}_{2} & {a}_{3} & … & {a}_{1}\end{matrix} ) )$$

can be represented as a polynomial in the form of a₁+a₂Z+a₃Z²+ . . . +a_{c}Z^{c-1} modulo Z^{c}+1. Where the size C of the circulant is a power of 2 (e.g., 16, 32, 64, 128 . . . ), the polynomial is not reducible. Addition and multiplication of circulants correspond to addition and multiplication of respective polynomials in ring modulo Z^{c}+1. For ease of computations of those matrices the following substitution X=Z+1 is made, so the multiplication and addition are performed in the polynomial ring modulo X^{c}.

The parity multiplier portion Hp is converted to the Smith Normal Form. Again, conversion to the Smith Normal Form may be done similar to that discussed in K. R. Matthews, “Smith Normal Form. MP274: Linear Algebra, Lecture Notes”, University of Queensland 1991. In making the conversion, the equation for p₂ is in the following form:

Lp×Dp×Rp×p₂=\tilde{H}u×u, and thus, p₂=(Rp)⁻¹×(\hat{D}p)⁻¹×(Lp)⁻¹×\tilde{H}u×u.

In the aforementioned equation, (Rp)⁻¹ and (Lp)⁻¹ are standard inverse matrices corresponding to Lp and Rp, respectively. In contrast, (\hat{D}p)⁻¹ is a pseudo inverse of the Dp matrix. Using the case of a one less matrix (i.e., a matrix of size m×n with a rank equal to the minimum of m an n less one), Dp has the following form:

$${D}_{p} = ( \begin{matrix}1 & 0 & … & 0 & 0 \\ 0 & 1 & … & 0 & 0 \\ … & … & … & … & … \\ 0 & 0 & … & 1 & 0 \\ 0 & 0 & … & 0 & Z + 1\end{matrix} ) .$$

As the corresponding pseudo-inverse matrix (\hat{D}p)⁻¹ is not quasi-circulant, it is represented in the following block form:

$${( {D}_{p} )}^{- 1} = ( \begin{matrix}1 & 0 & … & 0 & 0 \\ 0 & 1 & … & 0 & 0 \\ … & … & … & … & … \\ 0 & 0 & … & 1 & 0 \\ 0 & 0 & … & 0 & Z + 1\end{matrix} ) , \\ where$$

$$\hat{Q} = ( \begin{matrix}{\hat{Q}}_{1} & … & 0 \\ & & ⋮ \\ 0 & & 0\end{matrix} ) , \\ and$$

$$\hat{Q} = {( \begin{matrix}1 & 1 & 0 & … & 0 & 0 \\ 0 & 1 & 1 & … & 0 & 0 \\ … & … & … & … & … & … \\ 0 & 0 & 0 & … & 1 & 1\end{matrix} )}^{- 1} .$$

Said another way, the C−1 rows of the original matrix that correspond to the polynomial Z+1 are padded with zeros. All of these matrices may be pre-computed and stored to a run-time memory device. For all matrices of the same circulant size, (\hat{D}p)⁻¹ is the same.

Turning to FIG. 4b, one implementation of rank deficient LDPC encoder circuit 420 is shown in accordance with one or more embodiments of the present invention. As shown, rank deficient LDPC encoder circuit 420 includes a G-matrix memory 433 that is pre-programmed to include the aforementioned components:

Hu₁′, \tilde{H}u, (Lp)⁻¹, (\hat{D}p)⁻¹, (Rp)⁻¹, and Hp₁₂. In addition, rank deficient LDPC encoder circuit 420 includes a matrix multiplying circuit 403 that is tailored for multiplying a data input by a quasi-cyclic matrix. Matrix multiplying circuit 403 multiplies original data input 405 by component Hu₁′ to yield a parity portion p₁′.

In parallel to matrix multiplying circuit 403, a matrix multiplying circuit 406 that is tailored for multiplying a data input by a quasi-cyclic matrix multiplies original data input 405 by component \tilde{H}u to yield an interim value q₁. A matrix multiplying circuit 409 that is tailored for multiplying a data input by a quasi-cyclic matrix multiplies interim value q₁ by component (Lp)⁻¹ to yield an interim value q₂. A matrix multiplying circuit 412 that is tailored for multiplying a data input by a non-quasi-cyclic matrix multiplies interim value q₂ by a component (\hat{D}p)⁻¹ to yield an interim value q₃. A matrix multiplying circuit 418 that is tailored for multiplying a data input by a quasi-cyclic matrix multiplies interim value q₃ by component (Rp)⁻¹ to yield a parity portion p₂.

A vector addition circuit 424 operable to apply a modulo 2 vector addition adds parity portion p₂ to interim value q₁ to yield a parity portion p₁″. Each of parity portion p₁′, parity portion p₁″, parity portion p₂ and original data input 405 are provided to a codeword assembly circuit 436 that assembles the constituent parts of a codeword to be provided as encoded output 439. Any circuit known in the art for preparing an encoded output from the constituent parts may be used in relation to different embodiments of the present invention.

Returning to FIG. 4a, encoded output 439 is provided to a transmission circuit 430 that is operable to transmit the encoded data to a recipient via a medium 440. Transmission circuit 430 may be any circuit known in the art that is capable of transferring encoded output 439 via medium 440. Thus, for example, where data processing circuit 400 is part of a hard disk drive, transmission circuit 430 may include a read/write head assembly that converts an electrical signal into a series of magnetic signals appropriate for writing to a storage medium. Alternatively, where data processing circuit 400 is part of a wireless communication system, transmission circuit 430 may include a wireless transmitter that converts an electrical signal into a radio frequency signal appropriate for transmission via a wireless transmission medium. Transmission circuit 430 provides a transmission output to medium 440. Medium 440 provides a transmitted input that is the transmission output augmented with one or more errors introduced by the transference across medium 440.

Of note, original data input 405 may be any data set that is to be transmitted. For example, where data processing system 400 is a hard disk drive, original data input 405 may be a data set that is destined for storage on a storage medium. In such cases, a medium 440 of data processing system 400 is a storage medium. As another example, where data processing system 400 is a communication system, original data input 405 may be a data set that is destined to be transferred to a receiver via a transfer medium. Such transfer mediums may be, but are not limited to, wired or wireless transfer mediums. In such cases, a medium 440 of data processing system 400 is a transfer medium.

Data processing circuit 400 includes an analog processing circuit 450 that applies one or more analog functions to the transmitted input. Such analog functions may include, but are not limited to, amplification and filtering. Based upon the disclosure provided herein, one of ordinary skill in the art will recognize a variety of pre-processing circuitry that may be used in relation to different embodiments of the present invention. In addition, analog processing circuit 450 converts the processed signal into a series of corresponding digital samples. Data processing circuitry 460 applies data detection and/or data decoding algorithms to the series of digital samples to yield a data output 465. Based upon the disclosure provided herein, one of ordinary skill in the art will recognize a variety of data processing circuitry that may be used to recover original data input from the series of digital samples.

Turning to FIG. 5, a flow diagram 500 shows a method in accordance with one or more embodiments of the present invention for rank deficient LDPC encoding. Following flow diagram 500, a user data input (u) is received (block 505). The received user data input may be any data set that is to be encoded in preparation for transfer. As one example, where the transfer is to a storage medium, the received user data may be a data set that is destined for storage on a storage medium. In such cases, the medium by which the transfer will take place is the storage medium. As another example, where the transfer is to a receiver via a transmission medium, the received user data set may be a data set that is destined to be transferred to a receiver via the transmission medium. A matrix multiplication is applied where the received user data is multiplied by a user parity matrix (i.e., component Hu₁′) to yield a parity portion p₁′ (block 510).

In parallel to the matrix multiplication of the received user data by the user parity matrix (i.e., component Hu₁′) (block 510), a matrix multiplication is applied where the received user data is multiplied by a composite parity matrix (i.e., component \tilde{H}u) to yield a first interim value q₁ (block 515). A matrix multiplication is applied where the first interim value q₁ is multiplied by an inverse of the left factor of a Smith Normal result (i.e., component (Lp)⁻¹) to yield a second interim value q₂ (block 520). The second interim value q₂ is matrix multiplied by a pseudo inverse of the diagonal factor of a Smith Normal result (i.e., component (\hat{D}p)⁻¹) to yield a third interim value q₃ (block 525).

A matrix multiplication is applied where the third interim value q₃ is multiplied by an inverse of the right factor of a Smith Normal result (i.e., component (RP)⁻¹) to yield a parity portion p₂ (block 530). The parity portion p₂ is matrix multiplied by a parity matrix (i.e., component Hp₁₂) to yield a fourth interim value (block 535), and a vector addition is applied to add the resulting fourth interim value to the first interim value interim value q₁ to yield a parity portion p₁″ (block 540). Each of parity portion p₁′, parity portion p₁′, parity portion p₂ and the received user data are assembled together to yield a codeword for transfer (block 545).

Turning to FIG. 6, a flow diagram 600 shows a method in accordance with various embodiments of the present invention for generating encoding components. Following flow diagram 600, a parity matrix is received (block 605). The received matrix may be a sparse matrix represented in quasi-cyclic form. This matrix may be represented in the block form such as:

$$( \begin{matrix}{H}_{1 , 1} & … & {H}_{1 , n} \\ … & … & … \\ {H}_{m , 1} & … & {H}_{m , n}\end{matrix} ) ,$$

where each block (H_{i,j}) of size C×C is either a zero matrix or a cyclic matrix such as:

$${H}_{i , j} = ( \begin{matrix}{a}_{1} & {a}_{2} & … & {a}_{c} \\ {a}_{c} & {a}_{1} & … & {a}_{c - 1} \\ {a}_{2} & {a}_{3} & … & {a}_{1}\end{matrix} ) .$$

It should be noted that a quasi-cyclic matrix that includes only one non-zero element in each row of H_{i,j} is referred to as an identity matrix with rows shifted cyclically by the same value. Using such an identity matrix requires only the storage of the shift values for each circulant.

The columns and/or rows of the received matrix are permuted to a specific for parity matrix (block 610). Permuting the columns and/or rows of the received parity check matrix into the specific form includes taking a standard parity check matrix consisting of M×N circulant blocks of size C×C. Rows and columns of circulants are permuted so that the parity check matrix is in the form

$$H = ( \begin{matrix}{I}^{′} & 0 & 0 & {Hu}_{1}^{′} \\ 0 & {I}^{″} & {Hp}_{12} & {Hu}_{1}^{″} \\ {Hp}_{21}^{′} & {Hp}_{21}^{″} & {Hp}_{22}^{′} & {Hu}_{2}^{′}\end{matrix} ) ,$$

where 0 stands for all zero matrix, I′ and I″ stand for identity matrices of size M₁′·C and M₁″·C, respectively. Row blocks have the sizes: M₁′×C, M₁″×C and M₂×C respectively, where M₁′+M₁″+M₂=M Column blocks have sizes M₁′×C, M₁″×C, M₂×C, and K×C, where M₁′+M₁″+M₂+K=N.

All of the aforementioned Hu and Hp blocks are made of circulants. By denoting user bits (u) and parity bits (p) in the form (p,u), and splitting the parity bits into three component parts: p=(p₁′, p₁″, p₂), which have sizes M₁′×C, M₁″×C and M₂×C, respectively. Using such a notation, the parity check equations may be recast in the following format:

$$\{ \begin{matrix}{p}_{1}^{′} & & + {Hu}_{1}^{′} \times u = 0 \\ {p}_{1}^{″} & + {Hp}_{12} \times {p}_{2} & + {Hu}_{1}^{″} \times u = 0 \\ {Hp}_{21}^{′} \times {p}_{1}^{′} + {Hp}_{21}^{″} \times {p}_{1}^{″} & + {H}_{22}^{′} \times {p}_{2} & + {Hu}_{2} \times u = 0.\end{matrix}$$

The Hu₁′×u, Hu₁″×u and Hu₂×u components correspond to the user bits part of the parity check equations, and all of the other components correspond to the parity bits part of the parity check equations.

Components for Gaussian elimination are then calculated for the matrix in the specific form (block 615). The Gaussian elimination is performed over the last block row of the aforementioned parity check equations to yield updated parity check equations:

$$\{ \begin{matrix}{p}_{1}^{′} & & & + {Hu}_{1}^{′} \times u = 0 \\ & {p}_{1}^{″} & + {Hp}_{12} \times {p}_{2} & + {Hu}_{1}^{″} \times u = 0 \\ & & + \tilde{H} p \times {p}_{2} & + \tilde{H} u \times u = 0 ,\end{matrix}$$

where \tilde{H}p=Hp₂₁′×Hp₁₂+Hp₂₂′, and \tilde{H}u=Hp₂₁′×Hu₁′+Hp₂₁′×Hu₁″+Hu₂. Of note, the p₁′ part of parity bits may be calculated instantly after all user bits (u) are received. Since the H matrix was rank deficient, the parity multiplier portion \tilde{H}p is also rank deficient and can not be inverted. Thus the Thus p₂ cannot be calculated through simple multiplication by the inverse of the parity multiplier portion \tilde{H}p (i.e., (\tilde{H}p)⁻¹).

A circulant matrix

$$( e . g . , {H}_{i , j} = ( \begin{matrix}{a}_{1} & {a}_{2} & … & {a}_{c} \\ {a}_{c} & {a}_{1} & … & {a}_{c - 1} \\ {a}_{2} & {a}_{3} & … & {a}_{1}\end{matrix} ) )$$

can be represented as a polynomial in the form of a₁+a₂Z+a₃Z²+ . . . +a_{c}Z^{c-1} modulo Z^{c}+1. Where the size C of the circulant is a power of 2 (e.g., 16, 32, 64, 128 . . . ), the polynomial is not reducible. Addition and multiplication of circulants correspond to addition and multiplication of respective polynomials in ring modulo Z^{c}+1. For ease of computations of those matrices the following substitution X=Z+1 is made, so the multiplication and addition are performed in the polynomial ring modulo X^{c}.

Components for the Smith Normal form are calculated by converting the resulting parity multiplier portion \tilde{H}p to the Smith Normal Form (block 620). Again, conversion to the Smith Normal Form may be done similar to that discussed in K. R. Matthews, “Smith Normal Form. MP274: Linear Algebra, Lecture Notes”, University of Queensland 1991. In making the conversion, the equation for p₂ is in the following form:

Lp×Dp×Rp×p₂=\tilde{H}u×u, and thus, p₂=(Rp)⁻¹×(\hat{D}p)⁻¹×(Lp)⁻¹×\tilde{H}u×u.

In the aforementioned equation, (Rp)⁻¹ and (Lp)⁻¹ are standard inverse matrices corresponding to Lp and Rp, respectively. In contrast, (\hat{D}p)⁻¹ is a pseudo inverse of the Dp matrix. Using the case of a one less matrix (i.e., a matrix of size m×n with a rank equal to the minimum of m an n less one), Dp has the following form:

$${D}_{p} = ( \begin{matrix}1 & 0 & … & 0 & 0 \\ 0 & 1 & … & 0 & 0 \\ … & … & … & … & … \\ 0 & 0 & … & 1 & 0 \\ 0 & 0 & … & 0 & Z + 1\end{matrix} ) .$$

As the corresponding pseudo inverse matrix (\hat{D}p)⁻¹ is not quasi-circulant, it is represented in the following block form:

$${( {D}_{p} )}^{- 1} = ( \begin{matrix}1 & 0 & … & 0 & 0 \\ 0 & 1 & … & 0 & 0 \\ … & … & … & … & … \\ 0 & 0 & … & 1 & 0 \\ 0 & 0 & … & 0 & Z + 1\end{matrix} ) , \\ where$$

$$\hat{Q} = ( \begin{matrix}{\hat{Q}}_{1} & … & 0 \\ & & ⋮ \\ 0 & & 0\end{matrix} ) , \\ and$$

$$\hat{Q} = {( \begin{matrix}1 & 1 & 0 & … & 0 & 0 \\ 0 & 1 & 1 & … & 0 & 0 \\ … & … & … & … & … & … \\ 0 & 0 & 0 & … & 1 & 1\end{matrix} )}^{- 1} .$$

Said another way, the C−1 rows of the original matrix that correspond to the polynomial Z+1 are padded with zeros. All of these matrices may be pre-computed and stored to a run-time memory device. For all matrices of the same circulant size, (\hat{D}p)⁻¹ is the same.

At this juncture, all of the components to be used in relation to a data encoding have been calculated or generated. These components include the aforementioned Hu₁′, \tilde{H}u, (Lp)⁻¹, (\hat{D}p)⁻¹, (Rp)⁻¹, and Hp₁₂ components. These components are stored to a G-matrix memory of a data encoding circuit for use in encoding user data sets similar to that discussed above (block 625).

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the invention provides novel systems, devices, methods and arrangements for data processing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims

What is claimed is:

1. A data processing system, the system comprising:
an encoder circuit operable to:
receive a user data input;
matrix multiply the user data input by a first quasi-cyclic parity component to yield a first interim value;
matrix multiply the first interim value by an inverse left factor Smith Normal component to yield a second interim value;
matrix multiply the second interim value by a pseudo inverse diagonal factor Smith Normal component to yield a third interim value;
matrix multiply the third interim value by an inverse right factor Smith Normal component to yield a first parity portion;
matrix multiply the first parity portion by a second quasi-cyclic parity component to yield a fourth interim value; and
vector add the first interim value to the fourth interim value to yield a second parity portion.

2. The data processing system of claim 1, wherein the encoder circuit is further operable to:
assemble at least the user data input, the first parity portion, and the second parity portion into an encoded codeword.

3. The data processing system of claim 1, wherein the encoder circuit is further operable to:
matrix multiply the user data input by a third quasi-cyclic parity component to yield a third parity portion.

4. The data processing system of claim 3, wherein the encoder circuit is further operable to:
assemble the user data input, the first parity portion, the second parity portion and the third parity portion into an encoded codeword.

5. The data processing system of claim 3, wherein the encoder circuit includes a memory operable to store the first quasi-cyclic parity component, the inverse left factor Smith Normal component, the pseudo inverse diagonal factor Smith Normal component, the inverse left factor Smith Normal component, and the second quasi-cyclic parity component.

6. The data processing system of claim 5, wherein the encoder circuit includes:
a first matrix multiplier circuit operable to matrix multiply the user data input by the first quasi-cyclic parity component to yield the first interim value;
a second matrix multiplier circuit operable to matrix multiply the first interim value by the inverse left factor Smith Normal component to yield the second interim value;
a third matrix multiplier circuit operable to matrix multiply the second interim value by the pseudo inverse diagonal factor Smith Normal component to yield the third interim value;
a fourth matrix multiplier circuit operable to matrix multiply the third interim value by the inverse right factor Smith Normal component to yield the first parity portion;
a fifth matrix multiplier circuit operable to matrix multiply the first parity portion by a second quasi-cyclic parity component to yield a fourth interim value;
a vector addition circuit operable to vector add the first interim value to the fourth interim value to yield the second parity portion; and
a sixth matrix multiplier circuit operable to matrix multiply the user data input by the third quasi-cyclic parity component to yield the third parity portion.

7. The data processing system of claim 6, wherein each of the first matrix multiplier circuit, the second matrix multiplier circuit, the fourth matrix multiplier circuit, the fifth matrix multiplier circuit, and the sixth matrix multiplier circuit are configured to multiply an input by a quasi-cyclic matrix.

8. The data processing system of claim 6, wherein third matrix multiplier circuit is configured to multiply an input by a non-quasi-cyclic matrix.

9. The data processing system of claim 1, wherein the pseudo inverse diagonal factor Smith Normal component is a non-quasi-cyclic component.

10. The data processing system of claim 9, wherein both the inverse right factor Smith Normal component and the inverse left factor Smith Normal component are quasi-cyclic components.

11. The data processing system of claim 1, wherein the data processing system is implemented as part of a device selected from a group consisting of: a storage device, and a communication device.

12. The data processing system of claim 1, wherein the data processing system is implemented as part of an integrated circuit.

13. A method for data encoding, the method comprising:
calculating components for a rank deficient encoder, wherein the component calculation includes applying a Smith Normal conversion to an input matrix that yields left factor Smith Normal component, a diagonal factor Smith Normal conversion, and a right factor Smith Normal component;
inverting the left factor Smith Normal component to yield an inverse left factor Smith Normal component, wherein the inverse left factor Smith Normal component is a quasi-cyclic matrix;
inverting the diagonal factor Smith Normal component to yield a pseudo inverse diagonal factor Smith Normal component, wherein the pseudo inverse diagonal factor Smith Normal component is a non-quasi-cyclic matrix;
inverting the right factor Smith Normal component to yield an inverse left factor Smith Normal component, wherein the inverse left factor Smith Normal component is a quasi-cyclic matrix; and
storing the inverse left factor Smith Normal component, the pseudo inverse diagonal factor Smith Normal component, and the inverse right factor Smith Normal component to a memory device.

14. The method of claim 13, the method further comprising:
receiving a user data input;
matrix multiplying the user data input by a first quasi-cyclic parity component to yield a first interim value;
matrix multiplying the first interim value by the inverse left factor Smith Normal component to yield a second interim value;
matrix multiplying the second interim value by the pseudo inverse diagonal factor Smith Normal component to yield a third interim value;
matrix multiplying the third interim value by the inverse right factor Smith Normal component to yield a first parity portion;
matrix multiplying the first parity portion by a second quasi-cyclic parity component to yield a fourth interim value; and
vector adding the first interim value to the fourth interim value to yield a second parity portion.

15. The method of claim 14, wherein the method further comprises:
matrix multiplying the user data input by a third quasi-cyclic parity component to yield a third parity portion.

16. The method of claim 14, wherein the method further comprises:
assembling the user data input, the first parity portion, the second parity portion and the third parity portion into an encoded codeword.

17. The method of claim 14, wherein each of the matrix multiplying the user data input by the first quasi-cyclic parity component to yield the first interim value, matrix multiplying the first interim value by the inverse left factor Smith Normal component to yield the second interim value, matrix multiplying the third interim value by the inverse right factor Smith Normal component to yield the first parity portion, and matrix multiplying the first parity portion by the second quasi-cyclic parity component to yield the fourth interim value are done using respective matrix multiplier circuits configured to multiply an input by a quasi-cyclic matrix.

18. The method of claim 14, wherein matrix multiplying the second interim value by the pseudo inverse diagonal factor Smith Normal component to yield the third interim value is done using a matrix multiplier circuit configured to multiply an input by a non-quasi-cyclic matrix.

19. The method of claim 14, wherein the method further comprises:
transferring the encoded codeword to a destination selected from a group consisting of: a storage medium, and a receiver.

20. A data storage device, the device comprising:
a storage medium;
a head disposed in relation to the storage medium and operable to write an encoded data set to the storage medium;
an encoder circuit operable to:
receive a user data input;
matrix multiply the user data input by a first quasi-cyclic parity component to yield a first parity portion;
matrix multiply the user data input by a second quasi-cyclic parity component to yield a first interim value;
matrix multiply the first interim value by an inverse left factor Smith Normal component to yield a second interim value;
matrix multiply the second interim value by a pseudo inverse diagonal factor Smith Normal component to yield a third interim value;
matrix multiply the third interim value by an inverse right factor Smith Normal component to yield a third parity portion;
matrix multiply the third parity portion by a third quasi-cyclic parity component to yield a fourth interim value;
vector add the first interim value to the fourth interim value to yield a second parity portion; and
assemble the user data input, the first parity portion, the second parity portion and the third parity portion into an encoded codeword, wherein the encoded data set is derived from the encoded codeword.
